(19) United States
(12) Patent Application Publication
(10) Pub. No.: US 2026/0036910 A1
(43) Pub. Date: Feb. 5, 2026

(54) ANGLED BEAM EXPOSURE FOR HARDMASK BASED MODIFICATION

(71) Applicant: Tokyo Electron Limited, Tokyo (JP)

(72) Inventors: Shihsheng Chang, Albany, NY (US); Yen-Tien Lu, Albany, NY (US); Eric Chih-Fang Liu, Albany, NY (US); Minjoon Park, Albany, NY (US)

(21) Appl. No.: 18/791,007

(22) Filed: Jul. 31, 2024

(51) Int. Cl. G03F 7/00; H01J 37/08; H01L 21/311

(52) U.S. Cl. CPC G03F 7/70091; H01J 37/08; H01L 21/31116; H01J 2237/31711

(57) ABSTRACT

A method for processing a substrate includes receiving the substrate on a substrate holder disposed in a processing chamber, the substrate including a patterned hardmask disposed over an underlying layer, the patterned hardmask including features. The method further includes forming a first angle between a processing beam emitted from a processing nozzle and a normal direction of the substrate holder, the first angle selected such that the processing beam is shadowed from implanting into the underlying layer by adjacent features in the patterned hardmask, and emitting the processing beam at the first angle to modify a material of the patterned hardmask along a top surface of the patterned hardmask and along a sidewall of features in the patterned hardmask to form a modified hardmask. And the method further includes etching the underlying layer according to the modified hardmask.

### TECHNICAL FIELD

The present invention relates generally to a system and method for semiconductor fabrication, and, in particular embodiments, to a system and method for modifying a hardmask through angled beam exposure.

### BACKGROUND

The field of semiconductor fabrication continually seeks to enhance the precision and efficiency of manufacturing processes. As device dimensions shrink and complexity increases, the ability to precisely control feature geometries becomes increasingly crucial. Patterned hardmasks play a vital role in defining structures during semiconductor fabrication, serving as protective layers that enable selective material removal in subsequent etching steps.

In semiconductor fabrication, the precise control of feature geometries is paramount. As device dimensions continue to shrink, manufacturers are exploring various techniques to refine and enhance the patterning process. Advanced surface modification methods are being investigated for their potential to improve the fidelity and control of etching processes. These techniques aim to address the challenges associated with creating increasingly complex and miniaturized semiconductor structures, potentially offering new avenues for enhancing the capabilities and efficiency of semiconductor manufacturing processes.

### SUMMARY

In accordance with an embodiment of this disclosure, a method for processing a substrate includes receiving the substrate on a substrate holder disposed in a processing chamber, the substrate including a patterned hardmask disposed over an underlying layer, the patterned hardmask including features. The method further includes forming a first angle between a processing beam emitted from a processing nozzle and a normal direction of the substrate holder, the first angle selected such that the processing beam is shadowed from implanting into the underlying layer by adjacent features in the patterned hardmask, and emitting the processing beam at the first angle to modify a material of the patterned hardmask along a top surface of the patterned hardmask and along a sidewall of features in the patterned hardmask to form a modified hardmask. The modified hardmask including a first region and a second region, the first region being a same material as the patterned hardmask, and the second region being modified by the emitting of the processing beam to form a modified material. And the method further includes etching the underlying layer according to the modified hardmask, the second region being more etch resistant than the first region during the etching.

In accordance with another embodiment of this disclosure, a method for processing a substrate includes receiving the substrate on a substrate holder disposed in a processing chamber, the substrate including a patterned mask disposed over a layer to be processed. The method further includes aligning a beam to be at a first angle between a normal direction of a top surface of the substrate holder and a beam direction of a processing tool disposed in the processing chamber, and exposing the substrate to the beam from the processing tool to inject atoms into a first sidewall of the patterned mask to form a first region in the patterned mask. The method further includes aligning the beam to be at a second angle between the normal direction of the top surface of the substrate holder and the beam direction of the processing tool, and exposing the substrate to the beam from the processing tool to inject atoms into a second sidewall of the patterned mask to form a second region in the patterned mask. And the method further includes etching the substrate using an etch mask including the first region, the second region, and remaining regions of the patterned mask to form features in the layer to be processed.

And in accordance with yet another embodiment of this disclosure, a system for processing a substrate includes a scanning chamber coupled to a processing chamber through a rotatable feedthrough, a scanner disposed in the scanning chamber, the scanner including a substrate holder disposed on a scanning arm extending through the rotatable feedthrough into the processing chamber. The system further includes a processing tool coupled to the processing chamber through a processing nozzle, and a controller coupled to the scanner, the processing tool, the rotatable feedthrough, and a memory storing instructions to be executed in the controller. The instructions when executed cause the controller to receive the substrate on the substrate holder, the substrate including a patterned hardmask disposed over an underlying layer, the patterned hardmask including features, and form a first angle between a processing beam emitted from the processing nozzle and a normal direction of the substrate holder, the first angle selected such that the processing beam is shadowed from implanting into the underlying layer by adjacent features in the patterned hardmask. And the instructions when executed further cause the controller to emit the processing beam at the first angle to modify a material of the patterned hardmask along a top surface of the patterned hardmask and along a first sidewall of features in the patterned hardmask to form a modified hardmask, the modified hardmask including a first region and a second region, the first region being a same material as the patterned hardmask, and the second region being modified by the emitting of the processing beam to form a modified material.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1G are cross-sectional views of a substrate illustrating various steps of a method of modifying a hardmask in accordance with an embodiment of this disclosure;

FIGS. 2A-2B are cross-sectional views of a substrate illustrating various steps of a method of modifying a hardmask in accordance with an embodiment of this disclosure;

FIG. 3 is a schematic diagram of a processing system capable of implementing the method of modifying a hardmask in accordance with an embodiment of this disclosure;

FIG. 4 illustrates a schematic diagram of a processing system comprising a scanner in accordance with an embodiment of this disclosure;

FIGS. 5A-5B illustrate two cross-sectional views of a scanner loaded with a substrate in accordance with an embodiment of this disclosure;

FIGS. 6A-6C illustrate schematics of a scanner loaded with a substrate rotated through various angles, positioning the substrate at various tilt angles for modifying a hardmask, in accordance with an embodiment of this disclosure;

FIG. 7 is a flowchart of a method of modifying a hardmask in accordance with an embodiment of this disclosure; and

FIG. 8 is a flowchart of a method of modifying a hardmask in accordance with an embodiment of this disclosure.

### DETAILED DESCRIPTION OF ILLUSTRATIVE EMBODIMENTS

In the field of semiconductor manufacturing, achieving intricate and precise patterning on semiconductor wafers is crucial for the development of advanced integrated circuits and electronic devices. Hardmasks (formed and patterned using conventional lithographic processes) are typically used to transfer patterns onto underlying layers during etching processes. They are useful in defining fine features with high resolution and maintaining dimensional integrity throughout various fabrication steps.

However, traditional methods of transferring patterns onto underlying layers using patterned hardmasks (such as reactive ion etching (RIE) processes) often encounter difficulties with corner erosion of the hardmask. Further, the corner erosion of the patterned hardmask may cause defective etch profiles, which results in unsuccessfully transferring patterns to underlying layers. These issues can be exacerbated by subsequent etching processes, resulting in suboptimal feature transfer and unwanted deviations from the intended design. Such imperfections can adversely affect the performance and reliability of the resulting semiconductor devices.

Gas cluster technology has emerged as a promising approach in various surface modification applications owing to its ability to produce high-energy impacts with minimal surface damage. This involves the acceleration of clusters of gas atoms, which interact with the target surface to induce localized modifications. This technique has demonstrated potential in smoothing surfaces, improving material properties, and achieving precise control over nanoscale features.

This disclosure describes embodiment methods that use angled beam exposure to modify hardmask corners, and embodiment systems capable of implementing the embodiment methods. Through the utilization of gas clusters at oblique angles, the embodiment methods of this disclosure may ameliorate hardmask corner erosion. Further, the exposure to the gas clusters at oblique angles may modify sidewalls of the hardmask up to a penetration depth (which may be configurable through control of parameters of the gas clusters, such as energy, tilt angle, or exposure time) by strengthening, changing hardmask composition, or bonding gas clusters with material of the patterned hardmask. As a result, the strengthened or hardmask with modified composition or bonded gas cluster ions may alleviate corner sputtering in subsequent RIE processes. And consequently, the method of modifying a hardmask of this disclosure improves etch profiles over conventional methods. Another benefit of the method of this disclosure is the prevention of hardmask corner erosion improves the resolution and accuracy of pattern transfer while maintaining the structural integrity of the hardmask and underlying layers on a substrate. And an additional benefit of the method of this disclosure is that the modification of the hardmask through angled beam exposure is a more cost effective way of improving etch profiles without developing new hardmasks, which are costly development processes.

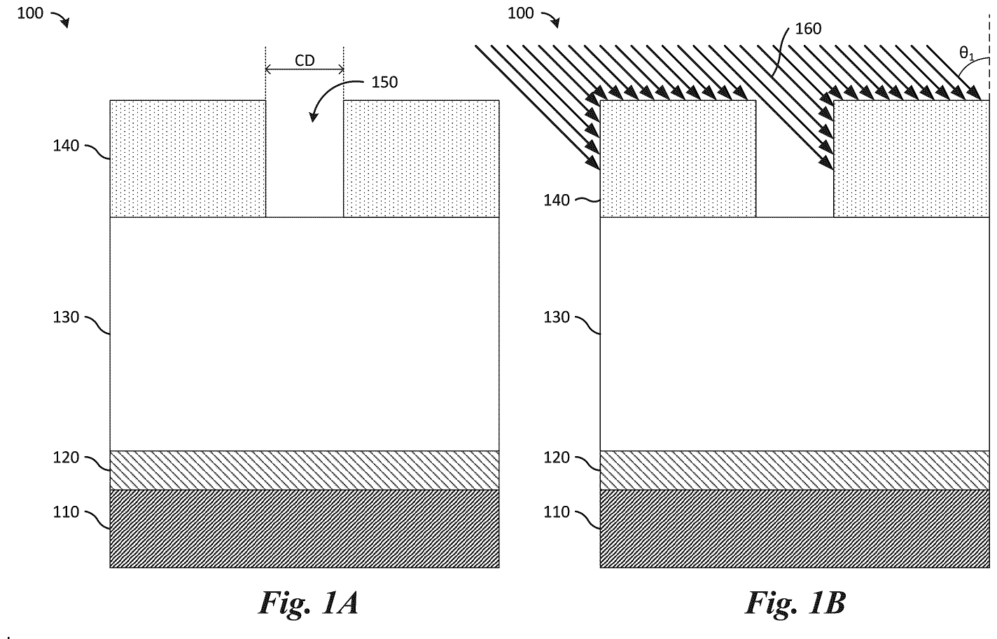

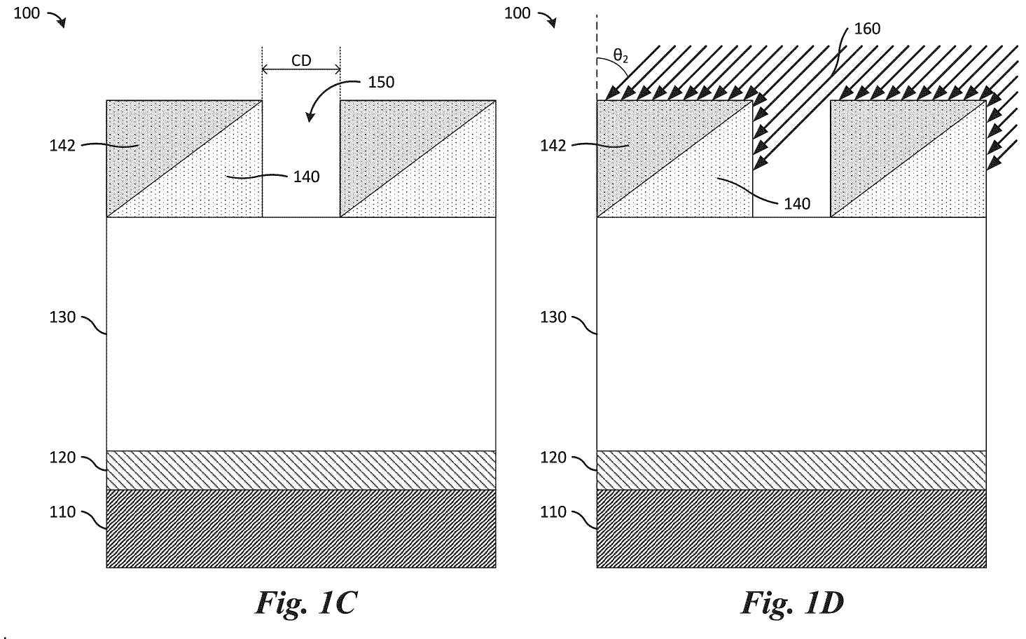

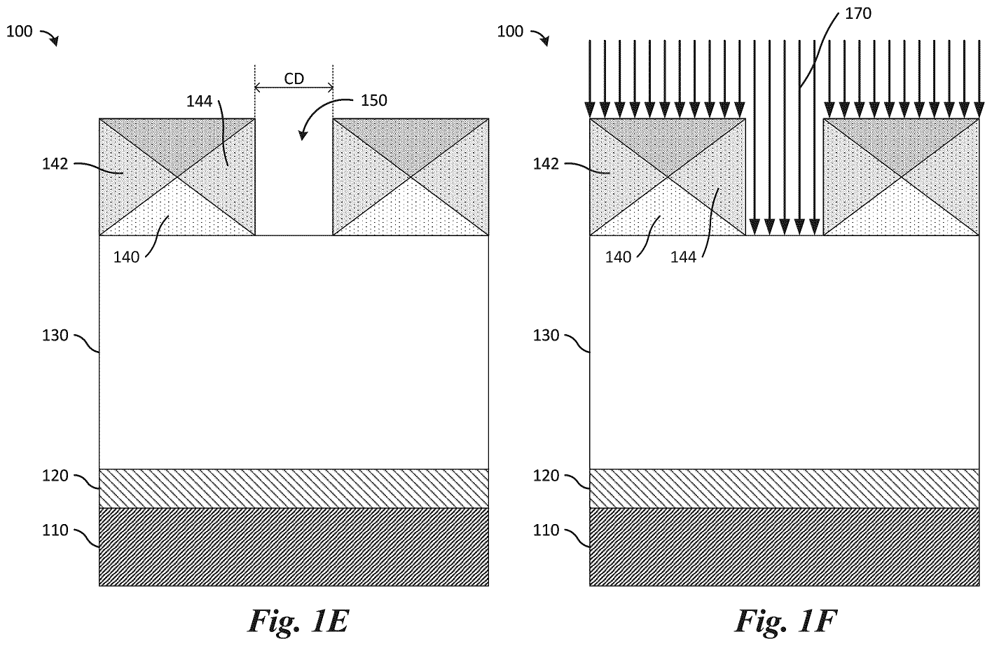

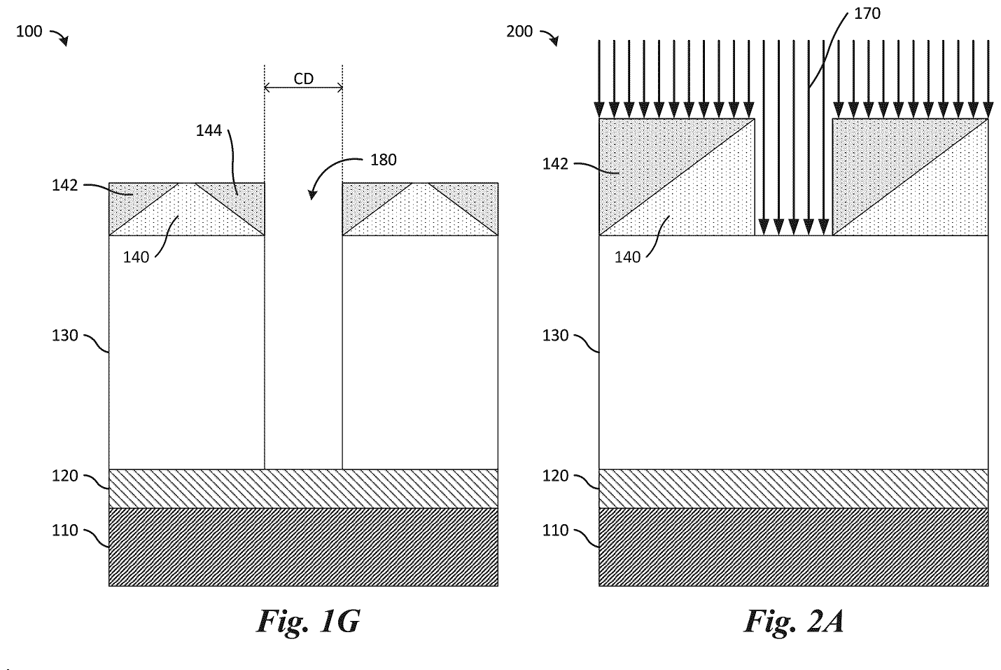

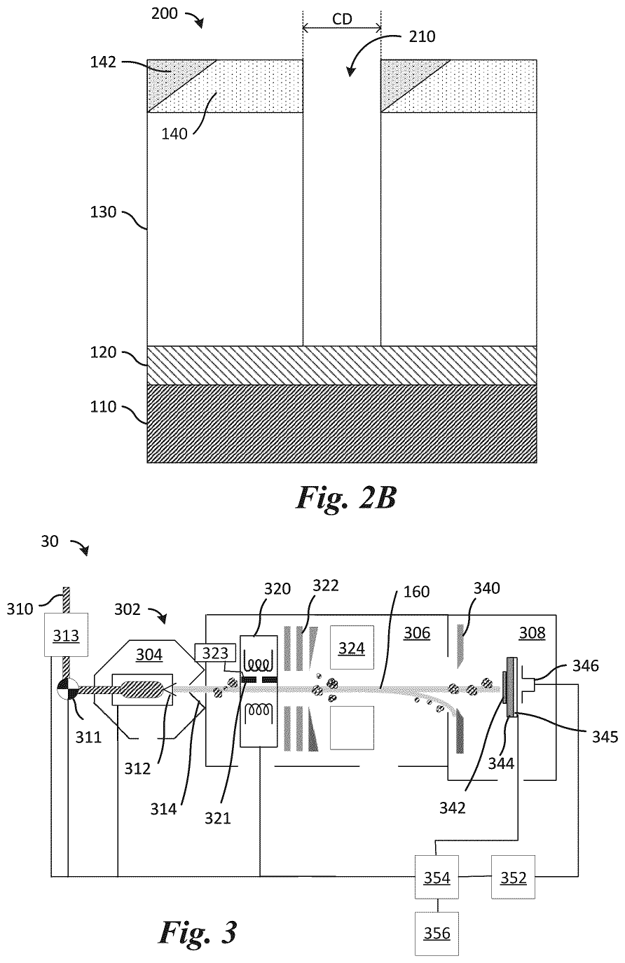

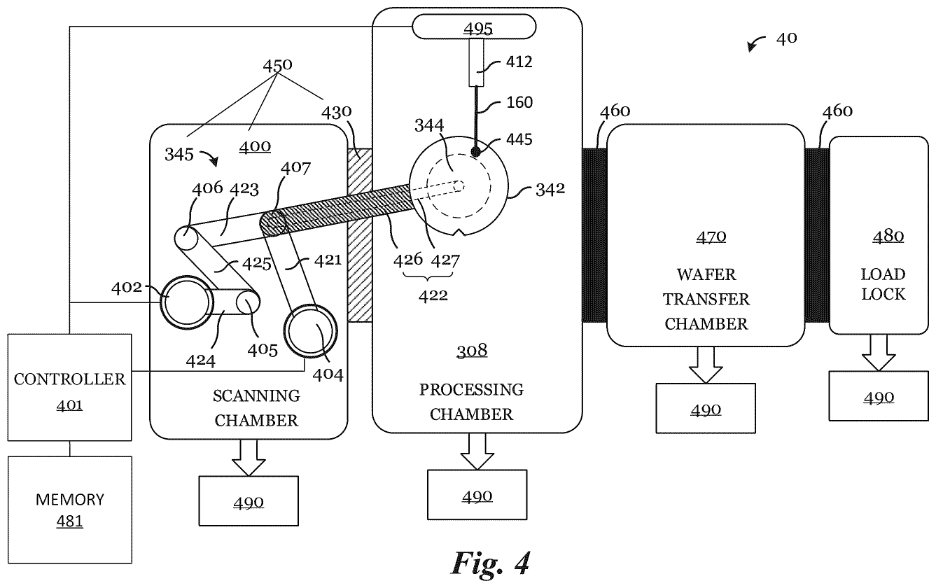

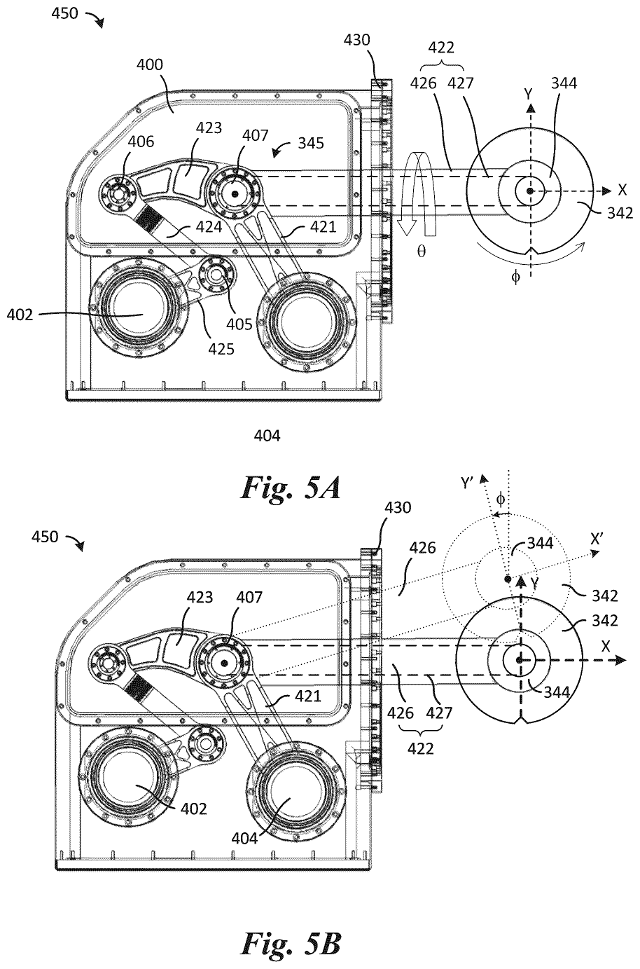

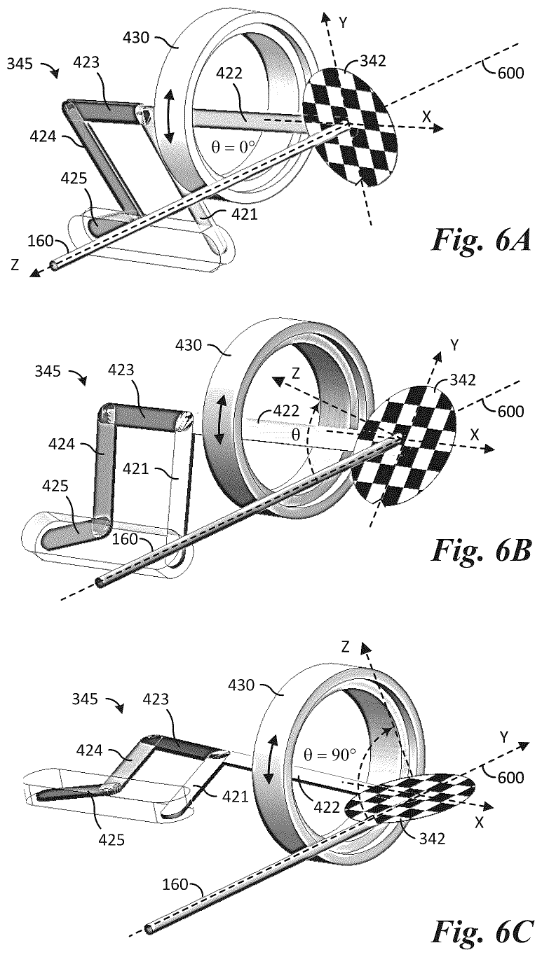

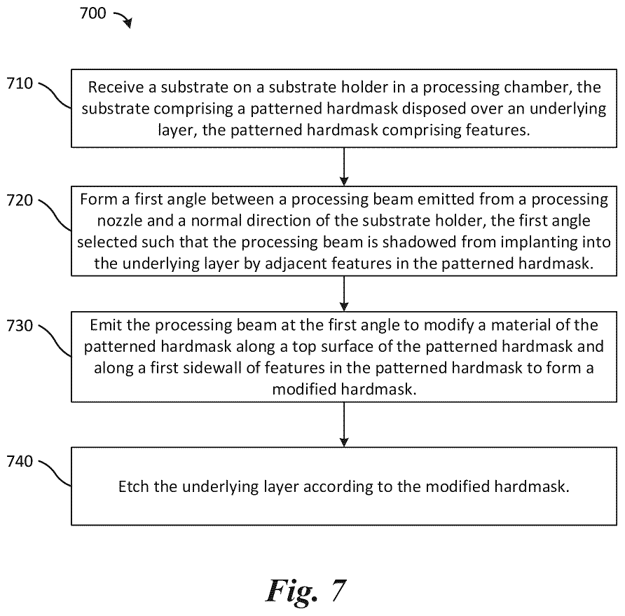

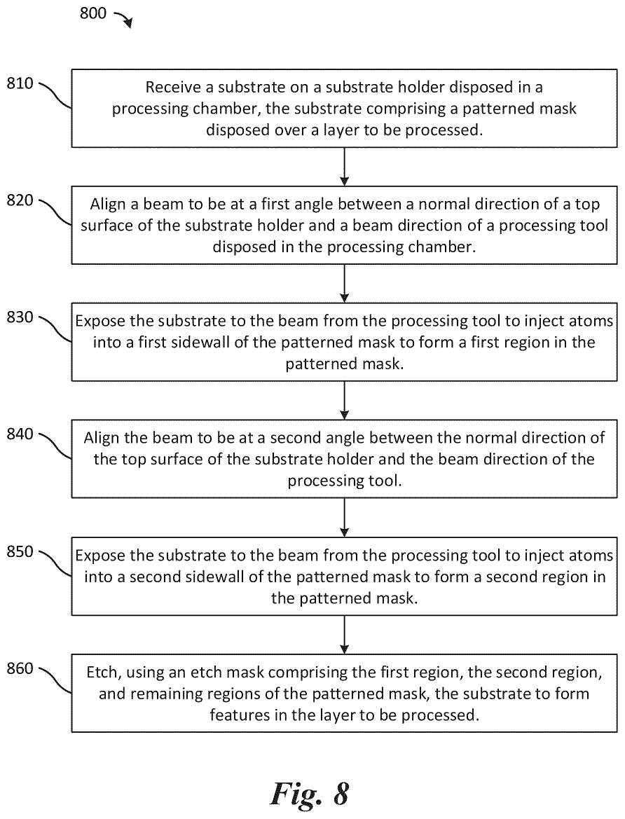

Embodiments provided below describe various methods, apparatuses and systems of processing a substrate, and in particular, to methods, apparatuses, and systems that use angled beam exposure to modify a patterned hardmask before processing the substrate. The following description describes the embodiments. FIGS. 1A-1G are used to describe various steps of a method for modifying a hardmask through illustrations of an example substrate. FIGS. 2A-2B are used to describe steps performed after FIG. 1C of an alternative embodiment of the method for modifying a hardmask. An example processing system which may implement the method of modifying a hardmask is described using FIG. 3. An additional processing system configured to perform the processing methods by modifying a hardmask through angled beam exposure is described using FIG. 4. FIGS. 5A-5B are used to describe a scanner which may be used to implement the method of modifying a hardmask through angled beam exposure. FIGS. 6A-6C are used to illustrate various tilt angles which may be used to modify a hardmask that the scanner of the processing systems of FIGS. 3-4 is capable of implementing. And FIGS. 7-8 are flowcharts used to illustrate two other example embodiment methods of modifying a hardmask through angled beam exposure before processing a substrate of this disclosure.

FIGS. 1A-1G are cross-sectional views of a structure 100 illustrating various steps of a method of modifying a hardmask in accordance with an embodiment of this disclosure.

FIG. 1A is a cross-sectional view of the structure 100, which may be a semiconductor structure. The structure 100 comprises a substrate 110 with multiple layers. At the bottom of the structure 100 is the substrate 110. Disposed on the substrate 110 is an underlying layer 120, which may be a semiconductor layer. And a dielectric layer 130 is disposed on the underlying layer 120, and may have been formed through conventional methods known in the art.

On top of the dielectric layer 130 is a patterned hardmask 140. The patterned hardmask 140 comprises an opening 150 in accordance with a feature pattern. Further, the opening 150 extends through the entire thickness of the patterned hardmask 140, exposing a portion of the upper surface of the dielectric layer 130. The patterned hardmask 140 may have been formed through conventional lithographic processes, such as a deposition followed by a light exposure process. Disposed on each side of the opening 150 are sidewalls of the patterned hardmask 140. The opening 150 has a feature critical dimension (CD) measured as the width of the opening at the top surface of the patterned hardmask 140. In various embodiments, the CD may be between about 20 nm to about 70 nm.

The substrate 110 may be any conventional semiconductor substrate suitable for forming the desired structure 100 using the method of modifying a hardmask through angled beam exposure of this disclosure. The substrate 110 may be any suitable substrate for which the method of modifying the hardmask through angled beam exposure may be desired to enable improved etch profiles of features formed. In various embodiments, the substrate 110 is a silicon wafer. Although the many substrates are circular, there is no limiting specification for the substrate 110 to be circular or even substantially circular. For example, the substrate 110 may be circular, square, rectangular, or any other desired shape including irregular shapes.

In various embodiments, the underlying layer 120 may comprise integrated circuit (IC) components that the opening 150 may be used to etch and form contacts, or other device features. In some embodiments, the underlying layer 120 is not present, and the method of this disclosure may be used to form features in the dielectric layer 130 after modifying the patterned hardmask 140 through angled beam exposure. In various embodiments, the dielectric layer 130 may comprise a layer stack of alternating dielectric layers, or a uniform dielectric material such as SiO₂, or Oxide/Nitride alternative layers. The dielectric layer 130 may also be referred to as a layer to be processed, or another underlying layer of the structure 100.

The patterned hardmask 140 may be formed of materials such as amorphous carbon (a-C) to form an amorphous carbon layer (ACL), patterned photoresists, or other suitable hardmask materials such as a metal-based hardmask.

Amorphous carbon layers (ACL) are widely used as hardmask materials due to their excellent etch selectivity and ability to form thin, uniform layers. ACLs are particularly effective for high-aspect-ratio etching processes and can be deposited using various methods such as chemical vapor deposition (CVD) or physical vapor deposition (PVD). As discussed in this application, ACLs can be strengthened and their etch resistance further improved, especially at the critical corner regions using gas cluster modification due to material property change. For ACL hardmasks, gas cluster modification using boron-containing gas clusters (such as diborane or B₂H₆) may be used.

Similarly, gas cluster modification of photoresists may enhance their etch resistance by inducing cross-linking of polymer chains and potentially incorporating elements from the gas clusters into the resist structure. In the case of photoresist hardmasks, gas cluster modification often employs hydrogen-containing or hydrocarbon-based gas clusters.

In some embodiments, the patterned hardmask 140 may be an amorphous carbon layer (ACL), and the dielectric layer 130 may be SiO₂. In other embodiments, the patterned hardmask 140 may be a patterned photoresist, and the dielectric layer 130 may be a suitable underlayer for forming the structure 100 or semiconductor device. The opening 150 in the patterned hardmask 140 defines a pattern that may be transferred to the underlying layers through subsequent processing steps, such as an etching process.

Maintaining an etch profile of the opening 150 in a conventional etch process impacts the dimensions of features formed in the underlying layers (the dielectric layer 130). Precise control of the CD, and limiting hardmask erosion may be enabled by modifying the patterned hardmask 140 through angled beam exposure by a beam of ions or gas clusters. And the limiting of the hardmask erosion using the method of this disclosure may enable the desired device performance and density in the final semiconductor structure.

The structure 100 may be used as a starting point for subsequent processing steps to form device features in the underlying layers of the structure 100 in accordance with an embodiment of this disclosure.

FIG. 1B illustrates a subsequent processing step performed on the semiconductor structure 100 shown in FIG. 1A. The structure 100 maintains the same layer stack, including the substrate 110, underlying layer 120, dielectric layer 130, and patterned hardmask 140 with opening 150.

In this step, the structure 100 is subjected to a beam 160 which is suitably focused. The beam 160 is directed at the surface of the structure 100 at a first angle θ₁ relative to the vertical axis projected from the surface of the substrate 110. The beam 160 may comprise ions of inert gases, reactive species, or a combination thereof. In various embodiments, the beam 160 may comprise gas clusters or ions from an ion implantation device. In other embodiments, where the desired depth of the patterned hardmask 140 desired to be modified is particularly shallow, the beam 160 may be a plasma jet from a plasma torch. In embodiments where the beam 160 comprises gas clusters, the beam 160 may be formed from a curing gas such as H or HBr. Further, in embodiments where the beam 160 comprises gas clusters, the beam 160 may comprise boron, such as B₂H₆. For example, for ACL based mask, boron-containing gases, particularly diborane (B₂H₆) may be used. In the case of photoresist hardmasks, hydrogen-containing or hydrocarbon-based gases such as hydrogen (H₂) or HBr may be used. These gases may induce additional cross-linking in the photoresist polymer structure, effectively hardening the material. The hydrogen in these gas clusters may also potentially terminate dangling bonds on the photoresist surface, which may improve its stability and etch resistance.

The exposure of the structure 100 to the beam 160 may be performed in a suitable processing system, such as processing system 30 in FIG. 3 or processing system 40 of FIG. 4. Further, different embodiments may use a scanner to scan a location specific beam 160 over portions of the surface of the substrate 110, while other embodiments may expose the entire surface of the substrate 110 to the beam 160 without scanning or using a scanner.

If a gas cluster process is used for hardmask modification, the total beam energy ranges from 30 to 60 keV. This high energy is necessary for accelerating the gas clusters and ensuring they reach the target surface with sufficient momentum. However, it is noted that this is the energy of the entire cluster, not individual atoms or molecules within the cluster. Upon impact with the target surface, the gas cluster disintegrates. The total energy of the cluster is distributed among its constituent atoms or molecules. Given that a typical gas cluster may contain hundreds or thousands of atoms, the energy per atom upon impact is dramatically reduced, usually to just a few electron volts (eV). This low per-atom energy is a critical feature of the gas cluster process. The relationship between the beam energy and impact energy per atom can be approximated as: Energy per atom≈(Total beam energy)/(Number of atoms per cluster). For example, if a 30 keV beam is used with clusters containing 1000 atoms each, the energy per atom upon impact would be approximately 30 eV. This low energy is sufficient for surface modification but typically insufficient for deep penetration or significant damage to the underlying material structure.

This energy distribution mechanism is what allows the gas cluster process to achieve shallow surface modification without the deep implantation or extensive damage associated with monatomic beams. The low per-atom energy enables confining the modification effects to the near-surface region, e.g., within the 2-20 nm range.

While both gas cluster technology and traditional ion implantation may be used in various embodiments they differ in the context of hardmask modification. Traditional ion implantation typically uses monatomic or small molecular ions because of which it is difficult to lower the energy per atom below a certain threshold without losing throughput. Hence, it is difficult to lower ion energy below 200-500 eV. Using smaller molecular ions such as BF₃ can partially offset this issue. In contrast, gas cluster technology uses large clusters of atoms or molecules, typically containing hundreds to thousands of atoms per cluster. While the total beam energy in gas cluster processes can be high (30-60 keV), this energy is distributed among all atoms in the cluster upon impact. Consequently, the energy per atom is much lower, typically just a few eV. This low per-atom energy results in very shallow penetration, usually limited to 2-20 nm from the surface.

In various embodiments, the first angle may be selected such that the top surface of the dielectric layer 130 is not exposed to the beam 160. In other words, the first angle may be chosen such that adjacent features (or openings 150) shadow the surface of the layer to be processed (the dielectric layer 130). This specification may be decided based on beam parameters of the beam 160 (such as beam energy, and exposure time), the feature CD of the openings 150, and the thickness of the patterned hardmask 140. For example, an implantation depth (or penetration depth) of the beam 160 may be between about 2-20 nm (which may depend on the beam energy), and the chosen angle may be selected such that a majority of the sidewalls of the openings 150 are exposed to the beam 160 without the beam 160 penetrating to the dielectric layer 130. Additionally, the first angle may be between 20° and 70°.

To determine the optimal angle, a calculation can be performed to find the smallest angle that allows modification of the hardmask sidewalls while preventing the gas clusters from reaching the underlying layer. For example, a simple assumption may use trigonometric calculations. In practice, the actual optimal angle may be slightly larger than the calculated minimum to account for beam spread and ensure uniform coverage. Different feature types, such as lines/spaces versus contact holes, may require angle adjustments. In some cases, multiple exposures at different angles may be necessary for complete coverage of all feature orientations.

The angled beam 160 impacts the sidewalls of the opening 150 in the patterned hardmask 140. This angled bombardment causes implantation of material into the patterned hardmask 140, particularly at the upper corners and sidewalls of the opening 150. Further, the implantation of material (such as injecting atoms) modifies the patterned hardmask 140 to change properties of the patterned hardmask 140 such as by strengthening to prevent hardmask erosion in the corners during subsequent processing steps.

As a result of this angled beam treatment, the material of the patterned hardmask 140 may be changed and form regions disposed throughout the patterned hardmask 140 based on the properties of the beam 160 and the amount of time the patterned hardmask 140 was exposed to the beam 160. The first angle θ₁ of the beam 160 may be carefully controlled to achieve the desired modification of the patterned hardmask 140. This angle can be adjusted based on the specifications of the fabrication process and the desired coverage of the sidewall of the openings 150.

FIG. 1C depicts the semiconductor structure 100 after the angled beam treatment shown in FIG. 1B. The basic layer stack remains unchanged, comprising the substrate 110, underlying layer 120, dielectric layer 130, and patterned hardmask 140 with opening 150.

The most notable change in this figure is the formation of a first modified region 142 in the patterned hardmask 140. The first modified region 142 is the result of the angled beam treatment modifying the material of the patterned hardmask 140. In various embodiments, the beam 160 may have implanted materials over a gradient of depths based on a spectrum of energies of the elements of the beam 160. For example, higher energy elements of the beam 160 may penetrate further than lower energy elements (or atoms), which results in a density gradient of the dopant material implanted by the beam 160 in the angled beam treatment (or oblique irradiation). In other embodiments, the density gradient of the first modified region 142 may be highest towards the surface of the patterned hardmask 140 and decrease the further into the patterned hardmask 140 penetrated by the beam 160 up to a penetration depth.

The first modified region 142 extends from the top surface of the patterned hardmask 140 and partway down the sidewalls of the opening 150. By modifying the patterned hardmask 140, the first modified region 142 (or first region) may be strengthened such that hardmask erosion is prevented. As a result, the etch profile of features formed using the modified patterned mask as an etch mask in subsequent etch steps is improved over conventional methods. Further, the prevention of corner erosion also prevents reflected etch species from colliding and subsequently sputtering material from sidewalls of features actively being etched into the underlying layers of the substrate 110, which improves the etch profile by preventing bow formation.

Despite the modification to the upper portion of the opening 150, the critical dimension (CD) at the bottom of the opening 150 remains largely unchanged. This preservation of the bottom CD is useful for maintaining control over the dimensions of features that will be formed in the underlying layers.

The formation of the first modified region 142 represents a controlled alteration of the patterned hardmask 140 profile. This modification may enhance subsequent processing steps, such as improving the uniformity of later etching processes, such as an RIE process.

The extent and shape of the first modified region 142 can be finely tuned by adjusting beam parameters of the beam 160 during the exposure illustrated in FIG. 1B, such as the first angle, energy, and duration of exposure. In some examples, an exposed corner of modified region 142 is modified more than the rest of the modified region 142 due to a difference of penetration depth into the patterned hardmask 140. After the formation of the first modified region 142 of the patterned hardmask 140, the method may expose an additional sidewall of the opening 150 in the patterned hardmask 140 to the beam 160, such as described using FIG. 1D.

FIG. 1D illustrates the semiconductor structure 100 during a second beam treatment. The basic layer stack remains consistent, comprising the substrate 110, underlying layer 120, dielectric layer 130, and patterned hardmask 140 with the opening 150 and first modified region 142.

The effectiveness of the hardmask modification process can be significantly enhanced by employing multiple exposure directions. This approach ensures comprehensive coverage of all feature orientations on the wafer, addressing the complex geometries often found in modern semiconductor designs. The desire for multiple direction exposure arises from the fact that semiconductor wafers typically contain features oriented in various directions, including orthogonal lines, contact holes, and more complex structures.

In its simplest form, a two-direction exposure can be implemented by irradiating the wafer from two opposite angles. This method is particularly effective for line/space patterns, where exposing from both sides ensures that both sidewalls of each line are adequately modified. However, for more complex structures or to achieve more uniform coverage, a four-direction exposure may be desired. This involves irradiating the wafer from four different angles, typically at 90-degree intervals, to cover features oriented in any direction on the wafer plane.

For the most comprehensive coverage, especially in cases involving circular features or to eliminate any potential shadowing effects, a circular or continuous rotational exposure can be employed. In this method, the wafer is continuously rotated while being exposed to the beam of gas clusters, ensuring that the beam interacts with the features from all possible angles. This approach, while potentially more time-consuming, provides the most thorough and uniform modification of the hardmask structures.

Implementing multiple direction exposure is enabled through careful coordination of the wafer handling system and the gas cluster source. For two- and four-direction exposures, the wafer can be rotated to predetermined angles between exposures. For circular exposure, a continuous rotation mechanism may be used.

In this step, the beam 160 is directed at the surface of the structure 100 at a second angle θ₂ relative to the vertical axis. The second angle θ₂ may be different from the first angle θ₁ used in the previous beam treatment (shown in FIG. 1B). For example, the second angle may be the same as the first angle but in the opposite direction to expose the opposite sidewall of the opening 150. Again, the second angle may be determined as similarly described for the first angle. And the second angle may be between 20° and 70°. In some embodiments, a different beam may be used as the beam 160 in the second beam treatment to modify the hardmask in accordance with an embodiment of this disclosure.

The beam 160 in the step illustrated in FIG. 1D impacts the sidewalls of the opening 150, and may also implant material (based on the penetration depth of the beam 160) within the first modified region 142. This treatment further modifies the patterned hardmask 140 to further cover the sidewalls of the openings to prevent hardmask erosion, particularly in the upper and middle portions of the patterned hardmask 140.

The critical dimension (CD) at the bottom of the opening 150 continues to be maintained, ensuring that the dimensions of features to be formed in the underlying layers remain controlled. Additionally, the second beam treatment, similar to the first beam treatment, does not implant or modify the dielectric layer 130 (or other underlying layers of the structure 100 disposed on the substrate 110).

FIG. 1E shows the semiconductor structure 100 after the second beam treatment depicted in FIG. 1D. The layer stack remains unchanged, and the structure 100 still comprises the substrate 110, underlying layer 120, dielectric layer 130, and patterned hardmask 140 with the opening 150 and first modified region 142.

The second beam treatment modified material of the patterned hardmask 140 and formed a second modified region 144. This second modified region 144 is the result of the cumulative effects of both beam treatments (shown in FIGS. 1B and 1D).

The second modified region 144 extends from the first modified region 142 further down the opposite sidewalls of the opening 150. Various embodiments may form differently shaped first and second modified regions 142 and 144 through different configurations of the first and second angles. Again, a density gradient may be formed in the second modified region 144 and be similarly described as for the possible density gradient of the first modified region 142.

The combination of the first modified region 142 and the second modified region 144 creates a modified sidewall in the opening 150, which may be strengthened to prevent corner erosion. By performing the second beam treatment, the patterned hardmask 140 comprises a first modified region 142 and a second modified region 144 (or second region) with increased strength to resist sputtering that may cause hardmask erosion. Other embodiments may only perform a single beam treatment depending on constraints of the subsequent etch process or the features being formed in the structure 100, such as described using FIGS. 2A-2B below.

As an example, embodiments where the structure 100 may form features that are highly dependent on suitable etch profiles without sputtering sidewalls may perform both treatments. Other embodiments may perform more than two beam treatments, or may rotate the substrate 110 tilted at the first angle to completely expose sidewalls of the openings 150 and modify the patterned hardmask 140.

FIG. 1F illustrates the semiconductor structure 100 undergoing a subsequent processing step, such as a reactive ion etching (RIE) process. The layer stack remains consistent, comprising the substrate 110, underlying layer 120, dielectric layer 130, and patterned hardmask 140 with the opening 150, and with the first modified region 142 and second modified region 144.

In this step, a processing beam 170 (such as an etching beam or plasma jet) is directed into the opening 150. The processing beam 170 is oriented vertically, perpendicular to the surface of the substrate. This beam may comprise ions, plasma, or other reactive species, depending on the specific process being performed. In the embodiment of FIG. 1F, the processing beam 170 is an etching beam, and the etching beam may be used to etch and transfer the feature pattern of the patterned hardmask 140 into the dielectric layer 130. As illustrated in FIG. 1F, the patterned hardmask 140 comprising openings 150, the first modified region 142 and the second modified region 144 is being used as an etch mask to process the structure 100.

The processing beam 170 interacts primarily with the exposed portion of the dielectric layer 130 at the bottom of the opening 150. This interaction can result in etching of the dielectric layer 130, initiating the transfer of the pattern defined by the patterned hardmask 140 into the underlying layers.

Conventional methods result in hardmask erosion during the processing step of FIG. 1F. In contrast to the conventional methods, the modified hardmask method of this disclosure has strengthened the patterned hardmask 140 such that hardmask erosion is prevented, which does not result in corner erosion that causes bow formation. And consequently, the method of this disclosure may transfer the features according to the feature pattern of the openings 150 of the patterned hardmask 140 to the underlying layers with improved etch profiles.

Various different forms of etching processes may be performed. In other embodiments, a wet etch process may be used in place of the processing beam 170. Embodiments that use a dry etch RIE process may use the processing beam 170, and the processing beam 170 may be any suitable plasma known in the art. For example, in various embodiments, the composition of the processing beam 170 may be optimally chosen to selectively etch material of the dielectric layer 130 without etching other material of the structure 100.

FIG. 1G depicts the semiconductor structure 100 after the processing step shown in FIG. 1F. The layer stack still includes the substrate 110, underlying layer 120, and the remaining portions of the dielectric layer 130 and patterned hardmask 140.

The most significant change in this figure is the formation of a feature opening 180. This opening extends through the dielectric layer 130, reaching the top surface of the underlying layer 120. The feature opening 180 is the result of the etching process illustrated in FIG. 1F. In various embodiments, the feature opening 180 may be a channel hole, a via, a trench, or a through via.

The shape of the feature opening 180 reflects the improved etch profile achieved by modifying the patterned hardmask 140 in accordance with an embodiment method of this disclosure. An additional benefit may be the preservation of the corners of the patterned hardmask 140 after the etch process. For example, in an embodiment where the structure 100 is a self-aligned contact (SAC), the preservation of the patterned hardmask corners by the angled beam exposure may improve the self-alignment capabilities of the SAC.

One of the challenges in SAC fabrication is the prevention of nitride corner loss during the contact etch process. In conventional SAC structures, the corners of the silicon nitride spacers that isolate the gate structures are susceptible to erosion during the oxide contact open. This corner erosion can lead to shorts between the contact and the other regions, compromising device performance and reliability.

The application of the modification process described in various embodiments of this disclosure to SAC fabrication may resolve these issues. By using a beam of gas clusters to treat corners of the silicon nitride spacers before the contact etch, it is possible to enhance the etch resistance of the nitride material. The shallow modification depth characteristic of the gas clusters is advantageous in this context, as it allows for strengthening of the nitride surface and corners without altering the bulk properties of the spacer material.

In one implementation, the gas cluster treatment would be applied after the formation of the nitride spacers but before the deposition of the interlayer dielectric (ILD) and subsequent contact etch. The gas chemistry for this application might include nitrogen-containing species to further nitride the surface, or other elements that can enhance the etch resistance of the silicon nitride. In another embodiment, the processing flow may implement the corner modification after performing a first partial etch of an oxide until a nitride is revealed, which may be followed by an oxide recess, and then use gas clusters to enhance the nitride corner. After, the oxide etch may resume until the contact has been fully opened.

The gas cluster process parameters, including beam energy, cluster size, and exposure angle, may be selected to ensure that the modification is concentrated at the top corners of the nitride spacers. Moreover, the gas cluster treatment can potentially improve the overall profile control of the SAC structure. By enhancing the etch selectivity between the modified nitride and the ILD material, it's possible to achieve more vertical contact sidewalls and better critical dimension (CD) control. This improved profile control can contribute to reduced contact resistance and enhanced device performance.

Still referring to FIG. 1G, the structure 100 demonstrates how the modification of the patterned hardmask 140 translates the features of the opening 150 into the dielectric layer 130 with an improved etch profile and without bow formation. The resulting structure sets the stage for subsequent processing steps, such as filling the opening with conductive materials to form interconnects with ICs of the underlying layer 120 or other device components. As opposed to FIGS. 1A-1G, another method of modifying a hardmask in accordance with an embodiment of this disclosure may only modify a single sidewall of the openings 150. Such an embodiment is described using FIGS. 2A-2B below.

The integration of hardmask modification into the semiconductor fabrication process flow may be enabled through the consideration of various factors to ensure compatibility with other processing steps. This technique is typically implemented after the initial hardmask patterning but before the main etching steps, allowing for enhanced etch resistance without disrupting the established lithographic processes. Accordingly, the modification step would be inserted immediately after the hardmask patterning step. This timing allows the modification to be applied to the patterned features, enhancing their resilience for subsequent processing. The placement of the gas cluster processing step may vary depending on the specific device structure and process details.

For photoresist-based hardmasks, the gas cluster modification would typically occur after the resist development step. This ensures that the modification is applied to the final patterned resist structure. In some cases, a brief descum or cleaning step might be performed before the gas cluster treatment to ensure optimal surface conditions for the modification process.

For hardmasks using materials like amorphous carbon or silicon nitride, the gas cluster modification may be performed after the initial patterning of these materials, which often involves a separate etch step to transfer the pattern from a top photoresist layer. In multi-layer hardmask stacks, the optimal timing of the gas cluster modification may depend on which layer is intended to serve as the primary etch-resistant component during the subsequent main etch.

Compatibility with subsequent processing steps is an additional consideration. The modified hardmask maintains its enhanced properties through any intervening steps between the gas cluster treatment and the main etch. This may include resist strip processes (in cases where the resist is not the primary hardmask), cleaning steps, or metrology operations.

In some advanced process flows, multiple gas cluster modification steps might be employed at different stages. For example, an initial modification might be performed on a bottom hardmask layer, followed by additional patterning steps and a second gas cluster treatment on a top hardmask layer. This approach can provide enhanced control over the final etch profile in complex multi-layer structures.

The integration of gas cluster modification may also impact metrology and inspection steps. The modified surface properties of the hardmask could affect critical dimension (CD) measurements or defect inspection processes. As such, it may be necessary to adjust metrology recipes or establish new baselines for process control.

FIGS. 2A-2B are cross-sectional views of a structure 200 illustrating various steps of a method of modifying a hardmask in accordance with an embodiment of this disclosure. In contrast to the method of modifying a hardmask illustrated by FIGS. 1A-1G, the method illustrated in FIGS. 2A-2B proceeds with etching the structure 200 after forming the first modified region 142.

FIG. 2A illustrates a processing step that occurs after the step shown in FIG. 1C. The structure 200 comprises the substrate 110, which comprises multiple layers similar to the previous figures. The layer stack of the structure 200 comprises the substrate 110 at the bottom, followed by the underlying layer 120, and the dielectric layer 130. On top of the dielectric layer 130 is the patterned hardmask 140 with the opening 150 and the first modified region 142 formed through the processing steps described for FIGS. 1A-1C. Similarly labeled elements may be as previously described.

In the step illustrated in FIG. 2A, the processing beam 170 is emitted over the structure 200 to transfer the pattern according to the opening 150 of the patterned hardmask 140 into the dielectric layer 130. In the embodiment illustrated in FIG. 2A, the processing beam 170 is oriented vertically, perpendicular to the surface of the substrate 110. The processing beam 170 may be as previously described, such as being a plasma jet used to etch the dielectric layer 130. Further, the processing beam 170 may comprise plasma, or other reactive species, depending on the specific process being performed.

The processing beam 170 primarily interacts with the exposed portion of the dielectric layer 130 at the bottom of the opening 150. This interaction can result in etching of the dielectric layer 130, initiating the transfer of the pattern defined by the hardmask 140 into the underlying layers.

The processing (or etching) illustrated in FIG. 2A may be as previously described for various embodiments as described using FIG. 1F, such as wet etch processes and dry etch processes. This processing step demonstrates how the modified hardmask, achieved through the previous beam treatment, can facilitate subsequent fabrication processes and contribute to the formation of precisely defined features in the semiconductor structure with improved etch profiles.

FIG. 2B depicts the semiconductor structure 200 after the processing step shown in FIG. 2A. The substrate 110 retains its multi-layer structure, including the substrate 110, underlying layer 120, and the remaining portions of the dielectric layer 130 and patterned hardmask 140.

The most significant change in this figure is the formation of a feature opening 210. This opening extends through the dielectric layer 130, reaching the top surface of the underlying layer 120. The feature opening 210 is the result of the vertical processing beam treatment shown in FIG. 2A.

The shape of the feature opening 210 reflects the profile of the hardmask opening 150, including the influence of the first modified region 142. And the feature opening 210 may be as previously describe for the feature opening 180 of FIG. 1G.

This figure demonstrates how the modified hardmask profile translates into the shape of the etched feature (feature opening 210) in the dielectric layer 130. The resulting structure 200 prepares the substrate 110 for subsequent processing steps, such as filling the opening with conductive materials to form interconnects or other device components.

The comparison between this figure and FIG. 1G illustrates how different hardmask modification processes can lead to variations in the final etched feature profile, allowing for tailored feature geometries based on device specifications. A processing system capable of implementing the method of modifying a hardmask through angled beam exposure of this disclosure is described using FIG. 3 below.

FIG. 3 is a schematic diagram of a processing system 30 capable of implementing the method of modifying a hardmask in accordance with an embodiment of this disclosure. For example, the processing system 30 may be capable of implementing the various embodiment methods of processing a substrate by modifying a hardmask using angled beam exposure described using FIGS. 1A-1G and FIGS. 2A-2B.

Referring to FIG. 3, the main body of the processing system 30 may be housed in a vacuum vessel 302 comprising three communicating chambers, namely, a source chamber 304, an acceleration chamber 306, and a processing chamber 308. The chambers may be evacuated to suitable operating pressures individually by vacuum pumping systems (not shown).

Gas clusters are formed in the source chamber 304. A source gas is introduced from a gas inlet 310 to the chamber 304 through a supersonic nozzle 312. A flow regulator 311 may regulate the flow of the gas through the gas inlet 310. A temperature controller 313 may be used to heat the gas to an appropriate temperature. Process parameters for gas cluster formation such as temperature, gas flow rates, and nozzle stagnation pressure may be controlled by the use of appropriate control systems (e.g., heaters and/or coolers, gas flow regulators, and pressure sensors) connected to the gas supply lines (not shown). In certain embodiments, the stagnation pressure may be between 70 to 500 kPa (525 Torr to 3.75×10³ Torr). A skimmer aperture 314 is positioned downstream from the nozzle 312, and configured to partially deflect or skim a peripheral portion of the gas cluster jet. In certain embodiments, more than one nozzle may be configured in mutual close proximity in the source chamber 304, wherein the nozzles may be arranged to supply different gas mixtures to form a single gas cluster beam. In certain embodiments, more than one skimmer may be used.

In the acceleration chamber 306, a charging source 320 comprises a metal filament, inductively coupled argon plasma source, or the like. The charging source 320 may comprise an extraction plate 321, in which a voltage exerted for charging the cluster may be measured, e.g., by a measurement circuit 323. Using the measurement circuit 323, a voltage response to an applied pulse at the charging source, e.g., a drive pulse train may be measured.

In certain embodiments, the gas cluster charging may be performed with a voltage between 70 and 300 eV. In certain embodiments, the charging source may further comprise a pulse generator to output a drive pulse train. In alternate embodiments, the pulse generator may be part of the control circuit of the system.

An accelerator 322 may be a set of biased electrodes, and configured to provide a set amount of kinetic energy to the gas clusters. In certain embodiments, the acceleration voltage may be between 30 and 80 keV.

A beam filter 324 is positioned after the accelerator 322 and configured to remove a portion of the gas cluster beam according to the size of clusters. In certain embodiments, the beam filter 324 may be a magnetic filter or Wien filter, a device comprising orthogonal electric and magnetic fields that can be used as a velocity filter to select a range of cluster sizes. A portion of the gas cluster beam may be deflected by the filter 324 to another trajectory from the main beam direction, and removed by a defining aperture 340. The degree of deflection for a cluster depends on its mass, and thereby enabling size filtering. In certain embodiments, the processing system 30 may further comprise a neutralizer (not shown) to neutralize the charge in the beam before the beam strikes a substrate 342.

In the processing chamber 308, a substrate 342 is mounted on a substrate holder 344 adequately positioned in the beam-line, and the substrate holder 344 is connected to a scanner 345. The scanner 345 may move the position of the substrate 342 relative to the beam-line in any direction in the plane perpendicular to the beam line. The scanner 345 may also have the ability to tilt the substrate 342 and change the incident angle of the beam, which may be used to enable the modification of a patterned hardmask of the substrate 342 in accordance with embodiments of this disclosure.

The spot size of a beam of gas clusters may vary from a few microns to a few centimeters. The processing chamber 308 may be kept in a high vacuum, for example, the pressure of the processing chamber 308 may be kept at or below 2.0×10⁻⁴ Pa (1.5×10⁻⁶ Torr).

A removable detector 346 may be positioned in the path of the beam, and configured to receive the beam and measure the beam current. In certain embodiments, the detector 346 is a Faraday cup or the like, which collects charges carried by the beam.

In various embodiments, the charges may be measured by a current sensing system 352 connected to the detector 346 (or the substrate holder 344). The current sensing system 352 may use any suitable current sensing technique including transformer or coils based on induction, magnetic field based sensors, and other techniques. In one embodiment, the current sensing system 352 may be an oscilloscope with an analog front-end circuit. The current sensing system 352 may further be connected to a high-speed acquisition capable hardware comprising a processor 354 and a non-transitory memory 356 with a high write speed to store digital signals connected through a high speed bus.

In various embodiments, the processor 354 may be a part of a tool controller configured to receive information about the gas clusters and send control signals to various units of the processing system 30, enabling a feedback control. In certain embodiments, the tool controller may directly instruct one or more units of the processing system 30 such as the control systems for a scanner 345, the nozzle 312 in the source chamber 304, the acceleration chamber 306, the flow regulator 311, and/or the temperature controller 313 to adjust one or more processing parameters. Alternately, the tool controller may send control signals to another hardware controller circuit that controls the operation of the control systems for the units of the processing system 30. An example processing system comprising a scanner which can tilt a substrate to enable the modification of a hardmask in accordance with embodiment methods of this disclosure is described using FIG. 4.

An embodiment processing system 40 capable of implementing the substrate processing method of this disclosure is described below using FIG. 4. The processing system 40 may be an embodiment of the processing system 30 of FIG. 3. In various embodiments, the processing system 40 may be a gas cluster system, or an ion implantation system.

The processing system 40 may be used to implement the processing method of this disclosure which uses angled beam exposure to modify a hardmask of a substrate before performing an etch step. In the embodiment illustrated in FIG. 4, an ion beam or a beam of gas clusters may be used to modify a patterned hardmask of the substrate 342.

The processing system 40 in FIG. 4 comprises a scanning chamber 400 that houses a scanning mechanism comprising actuators, moving parts, hinges, and the substrate holder 344, collectively referred to as the scanner 345; the processing chamber 308 where the substrate 342 (loaded onto the scanner 345) may intersect the beam 160 emitted over an area 445 of the substrate 342 by a processing nozzle 412 coupled with a processing tool 495 for processing the substrate 342; and a rotatable feedthrough 430 between the scanning chamber 400 and the processing chamber 308 through which a moving part of the scanner 345 can access and move the substrate 342 within the processing chamber 308. The combined continuous motion of the movable parts of the scanner 345 and discrete rotary motion of the scanning chamber 400 using the rotatable feedthrough 430 may provide the desired movements or tilt angles of the substrate 342 through the beam 160 to complete the modification of a hardmask of the substrate 342 in accordance with embodiment methods of this disclosure.

The processing system 40 is capable of implementing both blanket exposure and scanning methods. For blanket exposure, the processing nozzle 412 may be designed to emit a wide beam covering the entire area 445 of the substrate 342. For scanning applications, the scanner 345, in conjunction with the rotatable feedthrough 430, can move the substrate 342 relative to a more focused beam from the processing nozzle 412.

Though FIG. 4 illustrates the processing system 40 comprising a beam forming apparatus (such as a gas cluster or ion implantation system), other embodiments may use a plasma system to emit a plasma jet over the substrate 342 to modify the hardmask and thereby alleviate hardmask erosion. Accordingly, in this embodiment, the scanning chamber 400, the scanner 345, and the rotatable feedthrough 430 are together referred to as a scanning apparatus 450. The full range of motion of the scanning apparatus 450 and of the substrate 342 relative to the beam 160 impinging on its surface is described in further detail below.

A processing parameter which may be configured to control the material modification of the hardmask is a gas mixture used to form the beam 160. In other words, the gas mixture may comprise different mixtures of gases specifically tailored to the material of the patterned hardmask of the substrate 342 to appropriately strengthen the patterned hardmask to improve the etch profile formed in subsequent etching steps. For example, in an embodiment where the hardmask is an amorphous carbon layer (ACL), the gas mixture may comprise B₂H₆ or some other gas mixture comprising boron to form the beam 160. As another example, in other embodiments where the hardmask is a patterned photoresist, the gas mixture may comprise a curing gas such as hydrogen or HBr to form the beam 160. Other potential gas mixtures may comprise mixtures of AsH₃, PH₃, BF₃, GeF₄, SiF₄, He, Ar, N₂ for different hardmask materials and various shallow surface modifications.

The processing system 40 further comprises a load lock 480, where wafers for processing may be placed, and a wafer transfer chamber 470. The substrate 342 may be transported from the load lock 480 to the substrate holder 344 of the scanner 345 using, for example, an (r, θ, z) robotic arm located in the wafer transfer chamber 470. A wafer transfer window in the processing chamber 308 may be used to transfer the substrate 342 from the wafer transfer chamber 470 to the substrate holder 344.

The processing system further comprises a controller 401 to control the rotary drives of the scanning apparatus 450, and to control the various gas inlets and accelerators of a gas cluster generator or an ion implantation generator to form the beam 160 with the desired parameters for modifying the hardmask of the substrate 342 to prevent corner erosion and improve etch profiles. Further, the controller 401 may be coupled with the processing tool 495 to control various aspects of the processing tool to form the beam 160 emitted from the processing nozzle 412 over the substrate 342. In various embodiments, the processing tool 495 may be a gas cluster tool, an ion implantation tool, or a plasma tool (such as a plasma jet). The controller 401 may be used to implement the method of modifying a hardmask of this disclosure by executing instructions stored in a memory 481. The memory 481 may be any suitable storage device capable of storing the instructions to be executed by the controller to implement the processing method embodiments of this disclosure.

As illustrated in FIG. 4, the processing system 40 may comprise a vacuum system 490 connected to the scanning chamber 400, the processing chamber 308, the wafer transfer chamber 470, and the load lock 480. The connection between the scanning chamber 400 and the processing chamber 308 may be controlled by a rotary seal in the rotatable feedthrough 430, and the connections between the load lock 480, the wafer transfer chamber 470, and the processing chamber 308 may be controlled by two gate valves 460, as indicated schematically in FIG. 4. In one embodiment, this allows each chamber of the processing system 40 to be isolated and maintained at an independently controlled pressure using, for example, throttle valves. One advantage of having separate scanning and processing chambers is that it helps protect moving parts of the scanner 345 from contaminants originating in the processing chamber 308. In one embodiment, a controlled pressure difference between the scanning chamber 400 and the processing chamber 308 may be maintained to prevent byproducts produced inside the processing chamber 308 during the modification of the hardmask from entering the scanning chamber 400 and being deposited on the parts of the scanner 345.

The processing system 40 may be used to perform the substrate processing method of this disclosure which uses angled beam exposure to modify a hardmask to prevent hardmask erosion and improve etch profiles in subsequent etching steps. To enable the modification of the hardmask of the substrate, the processing system 40 uses the scanning apparatus 450, which may be described using the diagrams illustrated in FIGS. 5A-5B.

FIG. 5A illustrates a cross-sectional view of a prototype of the scanning apparatus 450 shown schematically in FIG. 4. In one embodiment, two rotary drives (a first rotary drive 402 and a second rotary drive 404) are used as the primary actuators of the scanner 345. One advantage of using rotary drives is cleanliness, hence lower maintenance cost because, unlike linear bearings, rotary bearings may be sealed from contaminants in the ambient environment. Synchronous angular displacements of the first and the second rotary drives 402 and 404 may be accurately computed in accordance with a desired planar trajectory of the center of the substrate holder 344, and subsequently used by a controller 401 (FIG. 4) to generate the computed synchronized rotational motions with high precision using, for example, electronically controllable motors. Control of backlash in the mechanical design of rotary parts may be beneficial for precise positioning of the substrate 342. Generally, the choices of drives, couplings and bearings are made to reduce backlash. The synchronized pair of rotations actuated by the first and the second rotary drives 402 and 404 is converted to a target scan trajectory of the center of the substrate holder 344 via various other moving parts of the scanner 345. The trajectory of the substrate holder 344, hence, also the trajectory of the substrate 342 loaded onto the substrate holder 344, is substantially coplanar with (or parallel to) the processing surface of the substrate 342.

In one embodiment, the rotational motion of the first and the second rotary drives 402 and 404 may be translated to a planar motion along the plane of the surface of substrate 342 using a bar-and-hinge system comprising five bar links (a first bar link 421, a second bar link 423, a third bar link 424, a fourth bar link 425, and a belted fifth bar link 422), and three hinges (a first hinge 405, a second hinge 406, and a third hinge 407) about which the bar links can rotate.

The belted fifth bar link 422 comprises a bar link 426 and a motorized belt-and-pulley system 427 in the bar link 426. The motorized belt-and-pulley system 427 may be used to orient the substrate 342 by rotating the planar surface of the substrate holder 344 along with the substrate 342. In various other embodiments, the mechanism used to rotate the substrate holder 344 may be implemented differently, as discussed in further detail below.

As illustrated in FIG. 5A, the first and the second rotary drives 402 and 404 are affixed to the body of the scanning chamber 400. Each rotary drive rotates one end of a respective bar link directly connected to the drive.

In FIG. 5A, the fourth bar link 425 is attached to the first rotary drive 402 and, at the opposite end, to a free moving first hinge 405. The first bar link 421, attached to the second rotary drive 404, has its opposite end connected to another free moving third hinge 407. The pair of synchronized rotations of the actuated first and fourth bar links 421 and 425 (synchronized by the controller, as described above) causes a respective synchronized pair of displacements of the first and the third hinges 405 and 407. The first and the third hinges 405 and 407 transmit the motion to other bar links attached to the first and the third hinges 405 and 407.

First hinge 405 is attached to one end of the third bar link 424, and third hinge 407 is attached to one end of the second bar link 423. The opposite ends of the second and the third bar links 423 and 424 are both connected to the second hinge 406. This causes a motion of the second hinge 406 conforming to the trigonometric relations between the angles of a triangle having two sides determined by the lengths of two bar links (second and third bar links 423 and 424) and the third side being the line segment connecting the first and the third hinges 405 and 407. The distance between the first and the third hinges 405 and 407 is determined by a combination of their synchronized displacements described above. In one embodiment, the repositioning of second hinge 406 determines the trajectory of the center of the substrate holder 344 (and of the substrate 342), as explained herein.

One end of the belted fifth bar link 422 has been attached to the substrate holder 344 and the opposite end is attached to the third hinge 407 and the second bar link 423. The connection between the second bar link 423 and the belted fifth bar link 422 allows the two-bar combination to pivot around the third hinge 407 while the angle formed by the two bars is held fixed. Accordingly, in this embodiment of the scanner 345, the location of the center of the substrate holder 344 is uniquely determined by the combined positions of second and third hinges 406 and 407 and the combined lengths of the second bar link 423 and the belted fifth bar link 422.

As illustrated in FIG. 5A, in one embodiment, the substrate 342 is placed on the substrate holder 344 such that the centers of the substrate holder 344 and substrate 342 are substantially coincident. The common center point is defined as the origin of a three-dimensional rectangular coordinate system (X, Y, Z), as illustrated in FIG. 5A and subsequent figures in this disclosure. The X-Y plane is the plane containing the planar trajectory derived from the synchronized rotations of the first and the second rotary drives 402 and 404, as described above. As illustrated in FIG. 5A, the X-Y plane is virtually the same (or coplanar) as the surface of the substrate 342 (or the substrate holder 344). Accordingly, the Z-axis (not visible in the two-dimensional view in FIG. 5A) points in a direction normal to this surface. The direction of the Y-axis could be selected along any particular orientation in the plane of the wafer. For specificity, in the figures in this disclosure, the Y-axis is selected to pass through a wafer notch. It is also customary to indicate a particular orientation of a crystalline semiconductor substrate by a physical mark on the wafer, such as the notch near the circumference of the circular substrate 342 in FIG. 5A.

The angle formed by the Z-axis (or any other line normal to the X-Y plane) and the processing beam (e.g., the beam 160) is referred to as the tilt angle, θ. As an example, the tilt angle (θ) may be either the first angle (θ₁) of the beam 160 in FIG. 1B or the second angle (θ₂) of the beam 160 in FIG. 1D. In FIG. 5A, the surface of the substrate 342 is vertical with the notch towards the bottom and, it is implicitly assumed that the beam 160 is incident horizontally perpendicular to the wafer surface, indicated as the X-Y plane. Accordingly, in FIG. 5A, the tilt angle is θ=0°.

In an embodiment, one side of the rotatable feedthrough 430 is attached rigidly (e.g., bolted) on to a wall of the scanning chamber 400. The opposite side may be placed on rotary bearings attached to an adjacent wall of the processing chamber 308, thereby allowing the scanning chamber 400 to be rotated about an axis passing through the center of the rotatable feedthrough 430 and normal to the wall of the processing chamber 308 to which the rotary part of the rotatable feedthrough 430 is attached. In one embodiment, the tilt angle, θ, may be adjusted by rotating the scanning chamber 400 and scanner 345 using the rotatable feedthrough 430, as indicated by the curved arrow in FIG. 5A.

The rotatable feedthrough 430 may rapidly rotate the scanning apparatus 450 to adjust the tilt angle θ to any desired value. In one embodiment, θ could be varied over a 155° range (−90°≤θ≤65°), and the substrate 342 could be moved from a horizontal loading position to a tilt of 65° in about 8 seconds to about 10 seconds. The beam 160 remains stationary, except for a displacement between the substrate 342 and the processing nozzle 412. As the substrate 342 is scanned through various positions at a configured tilt angle (θ) during processing, the height between the substrate 342 and the processing nozzle 412 may be adjusted using the controller 401 to control the processing tool 495 such that the size of the area 445 on the surface of the substrate 342 remains the same throughout processing (such as forming a modified hardmask as described using the illustrated steps of FIGS. 1A-1G and FIGS. 2A-2B). The tilted substrate 342 may be scanned through the beam 160 at the configured tilt angle by the scanner 345 to perform the method of modifying a hardmask of this disclosure. Further, the substrate 342 may be scanned at the tilt angle with the beam 160 striking the substrate 342 at a desired tilt angle (oblique irradiation) to implant ions to strengthen/modify the hardmask without modifying any underlying layers of the substrate 342. Other embodiments may expose the entire substrate 342 to the beam 160 at the desired tilt angle to modify the hardmask rather than scanning over the surface. Beam processing with a tilt angle, θ, is described in further detail below with reference to FIGS. 6A-6C.

Still referring to FIG. 5A, at any fixed tilt angle, θ, the substrate 342 may be rotated in-plane through a twist angle φ, without altering tilt angle θ, as indicated by an arc-shaped arrow in FIG. 5A. Generally, zero twist angle (φ=0°) is defined to be the orientation of the substrate 342 in FIG. 5A, where the notch is downwards when the substrate 342 is held vertically (θ=0°), perpendicular to a horizontal beam 160. Since the Y-axis is defined as coincident with the diameter which passes through the notch, the twist angle, φ, is the angular position of the Y-axis relative to the Y-axis at φ=0°. Accordingly, the twist angle, φ, may be defined to be the angle formed between the X-axis and a reference axis perpendicular to the planar face of the rotatable feedthrough 430. In one embodiment, φ may be set to any value in the range 0°≤φ≤360°, where, by convention, twist angle φ is considered to be increasing with counterclockwise rotation and decreasing with clockwise rotation. For example, if the substrate 342 in FIG. 5A were rotated a quarter-circle counterclockwise about the Z-axis then the notch would be towards the right, and φ=90°. For a rotation through a half-circle, φ=180°, and φ=270° for another quarter-circle beyond that.

Here, the Y-axis has been defined by the position of the notch, so altering the twist angle from 0° to φ is equivalent to rotating the X-Y axes about the Z-axis by a twist angle φ. The angles θ and φ are analogous to the polar angle and azimuthal angle, respectively, of a spherical coordinate system. Consider a substrate 342 positioned with a tilt angle, θ, and a twist angle, φ being scanned through the beam 160 by the scanner 345. Then θ is the angle formed by the Z-axis and the beam 160, and φ is the angle formed by the Y-axis and an orthogonal projection of the beam 160 on the X-Y plane.

In this embodiment, the substrate 342 may be loaded onto the substrate holder 344 at a particular wafer orientation (e.g., at φ=0°), and subsequently rotated about the Z-axis by a specified twist angle, φ. The loaded substrate 342 and the substrate holder 344 may be rotated together about an axis passing perpendicularly through the face of the rotatable feedthrough 430 by a tilt angle, θ, before moving the substrate through the beam 160. The tilt angle θ of the substrate 342 relative to the beam 160 alters the angle at which the beam strikes the substrate 342 and this may be used to modify the hardmask by implanting material in sidewalls of features in the patterned hardmask. As another example, in an embodiment, the second exposure to the beam 160 to form the second modified region 144 in the patterned hardmask 140 of FIG. 1D may be performed by rotating the twist angle 180° while maintaining the same tilt angle such that both sidewalls of the opening 150 are exposed to the beam 160 at the same angle to modify the patterned hardmask 140.

The twist angle may also influence the outcome of the processing. In-plane rotation through a twist angle φ, alters the position of the notch and, hence the orientation of all features exposed to the beam 160 on the substrate 342 (and crystal orientation if crystalline material is present, such as silicon) relative to the beam direction. Although, this does not alter the tilt angle (θ) of the surface of the substrate relative to the beam 160, altering the twist angle φ may alter, for example, the geometrical impact of an etch or implantation on a feature such as a long and narrow trench, or affect a dopant profile through a crystal orientation effect such as implant channeling.

Accordingly, it may be desirable the scanning apparatus 450 provides the capability to reduce variations in the tilt angle and the twist angle during the wafer scan. The substrate 342 may be loaded onto the substrate holder 344, oriented at a desired pair of values for tilt angle θ and twist angle φ and scanned through the beam 160 along a planar trajectory in the X-Y plane. The scanning motion generated using the rotary drives and the bar-and-hinge system of the scanner 345 may not affect the tilt angle, θ. In other embodiments, such as when the processing system 40 of FIG. 4 is being used to implement the method of modifying a hardmask described using FIGS. 1A-1G (or method 800 in the flowchart of FIG. 8), the tilt angle may be configured at a first angle, then the substrate is exposed over the desired surface, and then the tilt angle may be configured at a second angle, and then the substrate is exposed over the desired surface to modify the hardmask.

Generally, the values for tilt angle θ and twist angle φ are held roughly constant during a scan. For process steps where it is desired that the surface be exposed to the processing beam at several discrete combinations of tilt angle θ and twist angle φ the process recipe may be constructed to pass the substrate through several scans with the tilt and twist angles (θ, φ) combination being altered between successive scans. The twist angle may be adjusted without removing the substrate 342 from the substrate holder 344 using, for example, an electronically controlled motorized belt-and-pulley system 427.

Although the embodiments described in this disclosure are designed to maintain tilt and twist angles (θ, φ) roughly constant during a single scan of the entire wafer surface, it is understood that the scanning apparatus 450 may be modified to change the tilt angle θ, or the twist angle φ, or both in a single scan in a controlled manner. For example, one selected region of the substrate 342 may be scanned with one pair of values, a first pair of tilt and twist angles (θ₁, φ₁), the scan halted to change the controlled orientation to a different pair of values, a second pair of tilt and twist angles (θ₂, φ₂). After the change in orientation, a different region of substrate 342 may be scanned using the new pair of values, the second tilt and twist angles (θ₂, φ₂). The tilt angle, or the twist angle, or both may be dynamically controlled while the substrate 342 is being scanned through the beam 160. As mentioned above, in order to maintain a constant twist angle, φ, while the substrate 342 is scanned in the X-Y plane, the substrate 342 may be rotated dynamically without removing the substrate 342 from the substrate holder 344.

As described above with reference to FIG. 5A, and illustrated in FIG. 5B, the fifth bar link 426, by itself, is without the motorized belt-and-pulley system 427. The fifth bar link 426 and the motorized belt-and-pulley system 427 may be combined to form the belted bar link 422, which may also be described as a scanning arm. With the motorized belt-and-pulley system 427 of the belted fifth bar link 422, the planar surface of the substrate holder 344 (together with the substrate 342) may be able to rotate relative to the fifth bar link 426 of the belted fifth bar link 422. The rotation, being about the central axis normal to the planar surface, alters the twist angle, φ; hence the drive for the motorized belt-and-pulley system 427 is referred to as the twist drive. In one embodiment, the twist drive for the twist angle adjustment is embedded in the belted fifth bar link 422. In some other embodiments, the twist drive may be embedded in some other bar link.

FIGS. 6A-6C schematically illustrate beam processing (e.g., gas cluster processing, or plasma jet processing) of a substrate 342 by scanning the substrate 342 through a stationary beam 160 directed along a beam line 600. The substrate 342 is shown loaded on the scanner 345 (comprising the five bar links (first, second, third, and fourth bar links 421, 423, 424, and 425 and belted fifth bar link 422), described above with reference to FIG. 5A, and rotated by the rotatable feedthrough 430 to various tilt angles (θ).

In FIG. 6A, the beam 160 is illustrated to be incident perpendicular (θ=0°) to the surface of the substrate 342. Accordingly, the Z-axis in FIG. 6A is coincident with the beam line 600. FIG. 6C, illustrates the substrate 342 tilted to a horizontal position (θ=90°), similar to what may be used to transfer the wafer from a wafer transfer window. Accordingly, the Y-axis in FIG. 6C is coincident with the beam line 600. An intermediate tilt angle, θ, is illustrated in FIG. 6B. In all the three FIGS. 6A, 6B, and 6C, the twist angle φ=0°. Accordingly, it may be noted that, if the beam 160 were projected onto the X-Y plane, the projection would coincide with the Y-axis.

In various embodiments, the controller 401 in FIG. 4 may be used to control the first and second rotary drives 402 and 404 such that various tilt and twist angles (θ, φ) are maintained throughout processing of a substrate to modify a hardmask and subsequently etch to form features according to the modified hardmask. Specifically, the twist angle (φ) may be controlled by the second rotary drive 404 or a twist drive. Other embodiment processing systems may expose the entire substrate to a beam to modify the hardmask without using a scanner. Embodiment methods for modifying a patterned hardmask to prevent corner erosion and improve subsequent etch profiles formed by transferring features to underlying layers of a substrate are described using the flowcharts of FIGS. 7-8 below.

In various embodiments, the exposure of the substrate to the beam 160 may be performed using different methods. In one embodiment, the beam 160 may be applied as a sheet of beams that exposes the entire wafer surface simultaneously. This blanket exposure method allows for rapid processing of the entire substrate in a single step. In another embodiment, the beam 160 may be scanned across the surface of the substrate 342. The scanning method allows for more precise control over the exposure of specific areas of the substrate.

The processing system 40 may be configured to implement either the blanket exposure or the scanning method. In embodiments utilizing the scanning method, the scanner 345 may be used to move the substrate 342 relative to the beam 160, or alternatively, the beam 160 may be scanned across a stationary substrate. The choice between blanket exposure and scanning may depend on factors such as the desired precision, processing time, and the specific requirements of the features being modified.

For blanket exposure, the processing tool 495 may be configured to generate a wide beam that covers the entire substrate surface. In scanning embodiments, the processing tool 495 may generate a narrower, more focused beam, and the controller 401 may be programmed to coordinate the movement of the scanner 345 or the beam to ensure uniform coverage of the substrate surface.

FIGS. 7-8 are flowcharts illustrating example methods of modifying a hardmask in accordance with embodiments of the disclosure. The methods of FIGS. 7-8 may be combined with other methods and performed using the systems and apparatuses as described herein. For example, the methods of FIGS. 7-8 may be implemented in the processing system 30 of FIG. 3 or the processing system 40 of FIG. 4. Although shown in a logical order, the arrangement and numbering of the steps of FIGS. 7-8 are not intended to be limiting.

Referring to FIG. 7, step 710 of a method 700 of modifying a hardmask receives a substrate on a substrate holder in a processing chamber, the substrate comprising a patterned hardmask disposed over an underlying layer, the patterned hardmask comprising features. After, the method 700 forms a first angle between a processing beam emitted from a processing nozzle and a normal direction of the substrate holder in step 720. In step 720, the first angle is selected such that the processing beam is shadowed from implanting into the underlying layer by adjacent features in the patterned hardmask. The method may further include selecting either a blanket exposure of the entire substrate surface or a scanning exposure where the beam is scanned across the substrate surface. Step 730 of the method 700 emits the processing beam at the first angle to modify a material of the patterned hardmask along a top surface of the patterned hardmask and along a first sidewall of features in the patterned hardmask to form a modified hardmask. And the method 700, in step 740, etches the underlying layer according to the modified hardmask.

Now referring to FIG. 8, step 810 of a method 800 of modifying a hardmask receives a substrate on a substrate holder disposed in a processing chamber, the substrate comprising a patterned mask disposed over a layer to be processed. After, in step 820, the method 800 aligns a beam to be at a first angle between a normal direction of a top surface of the substrate holder and a beam direction of a processing tool disposed in the processing chamber. The method may further include selecting either a blanket exposure of the entire substrate surface or a scanning exposure where the beam is scanned across the substrate surface. Step 830 of the method 800 exposes the substrate to the beam from the processing tool to inject atoms into a first sidewall of the patterned mask to form a first region in the patterned mask. And the method 800, in step 840, aligns the beam to be at a second angle between the normal direction of the top surface of the substrate holder and the beam direction of the processing tool.

Still referring to FIG. 8, in step 850, the method 800 exposes the substrate to the beam from the processing tool to inject atoms into a second sidewall of the patterned mask to form a second region in the patterned mask. And the method 800, in step 860, etches, using an etch mask comprising the first region, the second region, and remaining regions of the patterned mask, the substrate to form features in the layer to be processed.

Example embodiments of the invention are described below. Other embodiments can also be understood from the entirety of the specification as well as the claims filed herein.

Example 1. A method for processing a substrate includes receiving the substrate on a substrate holder disposed in a processing chamber, the substrate including a patterned hardmask disposed over an underlying layer, the patterned hardmask including features. The method further includes forming a first angle between a processing beam emitted from a processing nozzle and a normal direction of the substrate holder, the first angle selected such that the processing beam is shadowed from implanting into the underlying layer by adjacent features in the patterned hardmask, and emitting the processing beam at the first angle to modify a material of the patterned hardmask along a top surface of the patterned hardmask and along a sidewall of features in the patterned hardmask to form a modified hardmask. The modified hardmask including a first region and a second region, the first region being a same material as the patterned hardmask, and the second region being modified by the emitting of the processing beam to form a modified material. And the method further includes etching the underlying layer according to the modified hardmask.

Example 2. The method of example 1, where the patterned hardmask is patterned photoresist, the underlying layer is SiO₂, the processing beam includes gas clusters comprising hydrogen, the first region includes patterned photoresist, and the second region includes hydrogen modified patterned photoresist.

Example 3. The method of one of examples 1 or 2, where the patterned hardmask is a patterned amorphous carbon layer (ACL), the underlying layer is a dielectric layer, the processing beam includes gas clusters comprising B₂H₆, the first region includes patterned ACL, and the second region includes B₂H₆ modified patterned ACL.

Example 4. The method of one of examples 1 to 3, where the first angle is between 20° and 70°.

Example 5. The method of one of examples 1 to 4, where the processing beam is a plasma jet for shallow modification of the underlying layer.

Example 6. The method of one of examples 1 to 5, where the modified hardmask includes a first material implanted by the processing beam and a second material of the patterned hardmask.

Example 7. The method of one of examples 1 to 6, where the processing beam is an ion beam emitted from an ion implantation device.

Example 8. The method of one of examples 1 to 7, where the top surface and the sidewall meet at the second region and the modified hardmask resists etching or sputtering in the second region compared to the first region.

Example 9. The method of one of examples 1 to 8, where the processing beam includes an interaction depth between 2 nm and 20 nm.

Example 10. The method of one of examples 1 to 9, where the interaction depth is determined by a beam energy of the processing beam, and the beam energy is between 30 keV and 60 keV.

Example 11. A method for processing a substrate includes receiving the substrate on a substrate holder disposed in a processing chamber, the substrate including a patterned mask disposed over a layer to be processed. The method further includes aligning a beam to be at a first angle between a normal direction of a top surface of the substrate holder and a beam direction of a processing tool disposed in the processing chamber, and exposing the substrate to the beam from the processing tool to inject atoms into a first sidewall of the patterned mask to form a first region in the patterned mask. The method further includes aligning the beam to be at a second angle between the normal direction of the top surface of the substrate holder and the beam direction of the processing tool, and exposing the substrate to the beam from the processing tool to inject atoms into a second sidewall of the patterned mask to form a second region in the patterned mask. And the method further includes etching the substrate using an etch mask including the first region, the second region, and remaining regions of the patterned mask to form features in the layer to be processed.

Example 12. The method of example 11, where the first angle is between 20° and 70°, and the second angle is the same as the first angle in an opposite direction.

Example 13. The method of one of examples 11 or 12, where the first angle is between 20° and 70°, the second angle is between 20° and 70°, and the first angle and the second angle are different.

Example 14. The method of one of examples 11 to 13, where exposing the substrate to the beam strengthens corners of the patterned mask.

Example 15. The method of one of examples 11 to 14, where the beam includes gas clusters comprising HBr, the patterned mask is patterned photoresist, and the layer to be patterned is SiO₂.

Example 16. The method of one of examples 11 to 15, where the beam includes gas clusters comprising B₂H₆, the patterned mask is a patterned amorphous carbon layer (ACL), and the layer to be patterned is a dielectric layer.

Example 17. A system for processing a substrate includes a scanning chamber coupled to a processing chamber through a rotatable feedthrough, a scanner disposed in the scanning chamber, the scanner including a substrate holder disposed on a scanning arm extending through the rotatable feedthrough into the processing chamber. The system further includes a processing tool coupled to the processing chamber through a processing nozzle, and a controller coupled to the scanner, the processing tool, the rotatable feedthrough, and a memory storing instructions to be executed in the controller. The instructions when executed cause the controller to receive the substrate on the substrate holder, the substrate including a patterned hardmask disposed over an underlying layer, the patterned hardmask including features, and form a first angle between a processing beam emitted from the processing nozzle and a normal direction of the substrate holder, the first angle selected such that the processing beam is shadowed from implanting into the underlying layer by adjacent features in the patterned hardmask. And the instructions when executed further cause the controller to emit the processing beam at the first angle to modify a material of the patterned hardmask along a top surface of the patterned hardmask and along a first sidewall of features in the patterned hardmask to form a modified hardmask, the modified hardmask including a first region and a second region, the first region being a same material as the patterned hardmask, the second region being modified by the emitting of the processing beam to form a modified material.

Example 18. The system of example 17, where the processing tool is a gas cluster tool, and the processing beam includes gas clusters.

Example 19. The system of one of examples 17 or 18, where the processing tool is an ion implantation device, and the processing beam is an ion beam.

Example 20. The system of one of examples 17 to 19, where the processing tool is a plasma torch, and the processing beam is a plasma jet.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for processing a substrate, the method comprising:
receiving the substrate on a substrate holder disposed in a processing chamber, the substrate comprising a patterned hardmask disposed over an underlying layer, the patterned hardmask comprising features;
forming a first angle between a processing beam emitted from a processing nozzle and a normal direction of the substrate holder, the first angle selected such that the processing beam is shadowed from implanting into the underlying layer by adjacent features in the patterned hardmask;
emitting the processing beam at the first angle to modify a material of the patterned hardmask along a top surface of the patterned hardmask and along a sidewall of features in the patterned hardmask to form a modified hardmask, the modified hardmask comprising a first region and a second region, the first region being a same material as the patterned hardmask, the second region being modified by the emitting of the processing beam to form a modified material; and
etching the underlying layer according to the modified hardmask, the second region being more etch resistant than the first region during the etching.

2. The method of claim 1, wherein the patterned hardmask is patterned photoresist, the underlying layer is SiO₂, the processing beam includes gas clusters comprising hydrogen, the first region comprising patterned photoresist, and the second region comprising hydrogen modified patterned photoresist.

3. The method of claim 1, wherein the patterned hardmask is a patterned amorphous carbon layer (ACL), the underlying layer is a dielectric layer, the processing beam includes gas clusters comprising B₂H₆, the first region comprising patterned ACL, and the second region comprising B₂H₆ modified patterned ACL.

4. The method of claim 1, wherein the first angle is between 20° and 70°.

5. The method of claim 1, wherein the processing beam is a plasma jet for shallow modification of the underlying layer.

6. The method of claim 1, wherein the modified hardmask comprises a first material implanted by the processing beam and a second material of the patterned hardmask.

7. The method of claim 1, wherein the processing beam is an ion beam emitted from an ion implantation device.

8. The method of claim 1, wherein the top surface and the sidewall meet at the second region and the modified hardmask resists etching or sputtering in the second region compared to the first region.

9. The method of claim 1, wherein the processing beam comprises an interaction depth between 2 nm and 20 nm.

10. The method of claim 9, wherein the interaction depth is determined by a beam energy of the processing beam, and the beam energy is between 30 keV and 60 keV.

11. A method for processing a substrate, the method comprising:
receiving the substrate on a substrate holder disposed in a processing chamber, the substrate comprising a patterned mask disposed over a layer to be processed;
aligning a beam to be at a first angle between a normal direction of a top surface of the substrate holder and a beam direction of a processing tool disposed in the processing chamber;
exposing the substrate to the beam from the processing tool to inject atoms into a first sidewall of the patterned mask to form a first region in the patterned mask;
aligning the beam to be at a second angle between the normal direction of the top surface of the substrate holder and the beam direction of the processing tool;
exposing the substrate to the beam from the processing tool to inject atoms into a second sidewall of the patterned mask to form a second region in the patterned mask; and
etching the substrate using an etch mask comprising the first region, the second region, and remaining regions of the patterned mask to form features in the layer to be processed.

12. The method of claim 11, wherein the first angle is between 20° and 70°, and the second angle is the same as the first angle in an opposite direction.

13. The method of claim 11, wherein the first angle is between 20° and 70°, the second angle is between 20° and 70°, and the first angle and the second angle are different.

14. The method of claim 11, wherein exposing the substrate to the beam strengthens corners of the patterned mask.

15. The method of claim 11, wherein the beam includes gas clusters comprising HBr, the patterned mask is patterned photoresist, and the layer to be patterned is SiO₂.

16. The method of claim 11, wherein the beam includes gas clusters comprising B₂H₆, the patterned mask is a patterned amorphous carbon layer (ACL), and the layer to be patterned is a dielectric layer.

17. A system for processing a substrate, the system comprising:
a scanning chamber coupled to a processing chamber through a rotatable feedthrough;
a scanner disposed in the scanning chamber, the scanner comprising a substrate holder disposed on a scanning arm extending through the rotatable feedthrough into the processing chamber;
a processing tool coupled to the processing chamber through a processing nozzle; and
a controller coupled to the scanner, the processing tool, the rotatable feedthrough, and a memory storing instructions to be executed in the controller, the instructions when executed cause the controller to:
receive the substrate on the substrate holder, the substrate comprising a patterned hardmask disposed over an underlying layer, the patterned hardmask comprising features;
form a first angle between a processing beam emitted from the processing nozzle and a normal direction of the substrate holder, the first angle selected such that the processing beam is shadowed from implanting into the underlying layer by adjacent features in the patterned hardmask; and
emit the processing beam at the first angle to modify a material of the patterned hardmask along a top surface of the patterned hardmask and along a first sidewall of features in the patterned hardmask to form a modified hardmask, the modified hardmask comprising a first region and a second region, the first region being a same material as the patterned hardmask, the second region being modified by the emitting of the processing beam to form a modified material.

18. The system of claim 17, wherein the processing tool is a gas cluster tool, and the processing beam includes gas clusters.

19. The system of claim 17, wherein the processing tool is an ion implantation device, and the processing beam is an ion beam.

20. The system of claim 17, wherein the processing tool is a plasma torch, and the processing beam is a plasma jet.
